(19) United States
(12) Patent Application Publication
(10) Pub. No.: US 2025/0153278 A1
(43) Pub. Date: May 15, 2025

(54) PROCESSING METHOD AND PROCESSING SYSTEM

(71) Applicant: Tokyo Electron Limited, Tokyo (JP)

(72) Inventor: Yohei YAMASHITA, Kikuchi-gun, Kumamoto (JP)

(73) Assignee: Tokyo Electron Limited, Tokyo (JP)

(21) Appl. No.: 18/839,180

(22) PCT Filed: Jan. 23, 2023
(86) PCT No.: PCT/JP2023/001867

§ 371 Date: Aug. 16, 2024

(30) Foreign Application Priority Data
Feb. 18, 2022 (JP) 2022-024175

(51) Int. Cl. B23K 26/53; B23K 26/03; B23K 26/042; B23K 101/40

(52) U.S. Cl. CPC B23K 26/53; B23K 26/032; B23K 26/042; B23K 2101/40

(57) ABSTRACT

A processing method of a combined substrate in which a first substrate and a second substrate are bonded to each other includes acquiring an eccentric amount between the first substrate and the second substrate; forming, by radiating internal laser light along a boundary between a peripheral portion of the first substrate and a central portion of the first substrate, a peripheral modification layer serving as a starting point of separation of the peripheral portion; and removing the peripheral portion starting from the peripheral modification layer. In the forming of the peripheral modification layer, an irradiation position of the internal laser light is determined based on the eccentric amount.

### TECHNICAL FIELD

The various aspects and embodiments described herein pertain generally to a processing method and a processing system.

### BACKGROUND

Patent Document 1 describes a substrate processing system including a modification layer forming apparatus configured to form a modification layer inside a first substrate along a boundary between a central portion and a to-be-removed peripheral portion of the first substrate in a combined substrate in which the first substrate and a second substrate are bonded to each other; and a periphery removing apparatus configured to remove the peripheral portion of the first substrate, starting from the modification layer.

### PRIOR ART DOCUMENT

Patent Document 1: International Publication No. 2019/176589

### DISCLOSURE OF THE INVENTION

### Problems to be Solved by the Invention

Exemplary embodiments provide a technique enabling appropriate removal of a peripheral portion of a first substrate in a combined substrate in which the first substrate and a second substrate are bonded to each other.

### Means for Solving the Problems

In an exemplary embodiment, a processing method of a combined substrate in which a first substrate and a second substrate are bonded to each other includes acquiring an eccentric amount between the first substrate and the second substrate; forming, by radiating internal laser light along a boundary between a peripheral portion of the first substrate and a central portion of the first substrate, a peripheral modification layer serving as a starting point of separation of the peripheral portion; and removing the peripheral portion starting from the peripheral modification layer. In the forming of the peripheral modification layer, an irradiation position of the internal laser light is determined based on the eccentric amount.

### Effect of the Invention

According to the exemplary embodiments, it is possible to appropriately remove the peripheral portion of the first substrate in the combined substrate in which the first substrate and the second substrate are bonded to each other.

### BRIEF DESCRIPTION OF THE DRAWINGS

FIG. 1 is a side view illustrating an example structure of a combined wafer to be processed.

FIG. 2 is a plan view illustrating a schematic configuration of a wafer processing system according to an exemplary embodiment.

FIG. 3 is a transversal cross sectional view illustrating a bonding strength reduction region, a peripheral modification layer, and a split modification layer formed in the combined wafer.

FIG. 4 is a side view illustrating a schematic configuration of an interface modifying apparatus and an internal modifying apparatus.

FIG. 5 is an explanatory diagram illustrating how a deviation amount detector works.

FIG. 6 is an explanatory diagram illustrating another arrangement of the deviation amount detector.

FIG. 7 is a side view illustrating another configuration example of the interface modifying apparatus and the internal modifying apparatus.

FIG. 8 is a flowchart illustrating main processes of a wafer processing in the wafer processing system.

FIG. 9 is an explanatory diagram showing an example of a measurement result by the deviation amount detector.

FIG. 10A to FIG. 10C are explanatory diagrams illustrating the main processes of the wafer processing in the wafer processing system.

FIG. 11 is a side view illustrating another example configuration of the interface modifying apparatus and the internal modifying apparatus.

FIG. 12A to FIG. 12D are explanatory diagrams illustrating another example of forming a bonding strength reduction region.

FIG. 13 is an explanatory diagram illustrating another example of forming the peripheral modification layer.

FIG. 14 is an explanatory diagram illustrating still another example of forming the peripheral modification layer.

FIG. 15A to FIG. 15D are explanatory diagrams illustrating other processes of the wafer processing in the wafer processing system.

### DETAILED DESCRIPTION

In a manufacturing process for a semiconductor device, in a combined substrate in which a first substrate (a silicon substrate such as a semiconductor) having devices such as a plurality of electronic circuits formed on a front surface thereof and a second substrate are bonded to each other, removal of a peripheral portion of the first substrate, so-called edge trimming, may be performed. In this edge trimming, the peripheral portion of the first substrate is removed with a predetermined trim width by using an outer end of the first substrate as a reference, for example.

The edge trimming of the first substrate is performed by using a substrate processing system described in, for example, Patent Document 1. That is, a modification layer is formed by radiating first laser light to an inside of the first substrate form the first substrate side, and the peripheral portion of the first substrate is removed starting from the modification layer. Further, according to the substrate processing system disclosed in Patent Document 1, by radiating second laser light to an interface at which the first substrate and the second substrate are bonded, a modification surface is formed to reduce bonding strength between the first substrate and the second substrate at the peripheral portion, thus enabling appropriate removal of the peripheral portion.

In the combined substrate as a processing target, there may be a positional misalignment between the first substrate and the second substrate due to, for example, bonding accuracy in a bonding apparatus. In this case, if there is a request to make the trim width of the first substrate uniform with respect to an end portion of the second substrate, it is difficult to meet this request.

Further, the first laser light for forming the aforementioned modification layer may be radiated from the first substrate side, and the second laser light for forming the aforementioned modification surface may be radiated from the second substrate side. In other words, the system may perform a process in which the radiation of the laser light from the first substrate side and the radiation of the laser light from the second substrate side are both performed.

However, when both the radiation of the laser light from the top side of the combined substrate and the radiation of the laser from the bottom side of the combined substrate are performed in this way, if there exists the aforementioned positional misalignment between the first substrate and the second substrate, it is difficult to match the radiation positions of the first laser light from the first substrate side and the second laser light from the second substrate side, which may raise a risk that the peripheral portion of the first substrate may not be properly removed.

In view of the foregoing, exemplary embodiments provide a technique enabling appropriate removal of the peripheral portion of the first substrate in the combined substrate in which the first substrate and the second substrate are bonded to each other. Hereinafter, a wafer processing system as a processing system and a wafer processing method as a processing method according to exemplary embodiments will be described with reference to the accompanying drawings. In the present specification and the drawings, parts having substantially the same functions and configurations will be assigned same reference numerals, and redundant description thereof will be omitted.

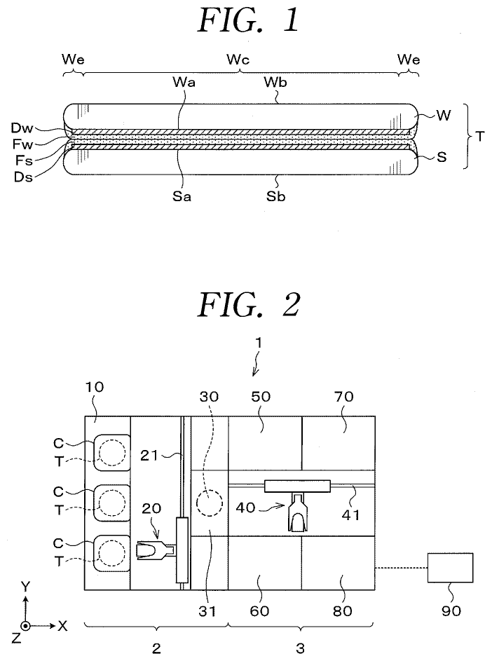

In a wafer processing system 1 to be described later according to the present exemplary embodiment, a combined wafer T in which a first wafer W and a second wafer S are bonded to each other as shown in FIG. 1 is processed. A wafer is an example of a substrate. Hereinafter, in the first wafer W, a surface bonded to the second wafer S is referred to as a front surface Wa, and a surface opposite to the front surface Wa is referred to as a rear surface Wb. Likewise, in the second wafer S, a surface bonded to the first wafer W is referred to as a front surface Sa, and a surface opposite to the front surface Sa is referred to as a rear surface Sb.

The first wafer W is, for example, a semiconductor wafer such as a silicon substrate, and a device layer Dw including a plurality of devices is formed on the front surface Wa thereof. Further, a bonding film Fw is further formed on the device layer Dw, and the first wafer W is bonded to the second wafer S with the bonding film Fw therebetween. An oxide film (a THOX film, a SiO₂ film, a TEOS film, etc.), a SiC film, a SiCN film, or an adhesive is used as an example of the bonding film Fw. Further, a peripheral portion We of the first wafer W is chamfered, and the thickness of this peripheral portion We decreases toward a leading end thereof on a cross section thereof. Furthermore, the peripheral portion We is a portion to be removed in edge trimming to be described later, and is in the range of 0.5 mm to 3 mm from an edge of the first wafer W in a diametrical direction. In the following description, a portion of the first wafer W, which is inner side than the peripheral portion We to be removed in the diametrical direction, will sometimes be referred to as a central portion Wc.

The second wafer S has, for example, the same structure as the first wafer W. A device layer Ds and a bonding film Fs are formed on the front surface Sa, and a peripheral portion of the second wafer S is chamfered. However, the second wafer S does not need to be a device wafer on which the device layer Ds is formed, but it may be, for example, a support wafer that supports the first wafer W. In this case, the second wafer S functions as a protective member that protects the device layer Dw of the first wafer W.

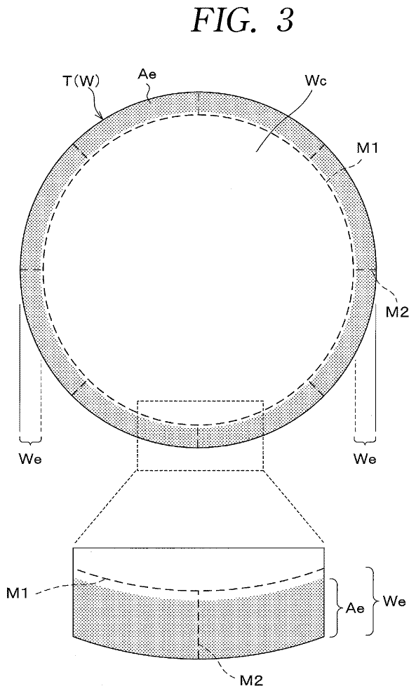

As depicted in FIG. 2, the wafer processing system 1 has a configuration in which a carry-in/out station 2 and a processing station 3 are connected as one body. In the carry-in/out station 2, a cassette C capable of accommodating therein a plurality of combined wafers T is carried to/from the outside, for example. The processing station 3 is equipped with various types of processing apparatuses configured to perform required processings on the combined wafer T.

The carry-in/out station 2 is equipped with a cassette placement table 10 on which the cassette C capable of accommodating therein the plurality of combined wafers T is placed. Further, a wafer transfer device 20 is provided adjacent to the cassette placement table 10 on the positive X-axis side of the cassette placement table 10. The wafer transfer device 20 is configured to be moved on a transfer path 21 extending in the Y-axis direction to transfer the combined wafer T between the cassette C of the cassette placement table 10 and a transition device 30 to be described later.

In the carry-in/out station 2, the transition device 30 and an inverting device 31 are provided adjacent to the wafer transfer device 20 on the positive X-axis side of the wafer transfer device 20. The transition device 30 and the inverting device 31 are stacked on top of each other.

The transition device 30 is configured to temporarily hold the combined wafer T transferred between the carry-in/out station 2 and the processing station 3. The inverting device 31 is configured to invert front and rear surfaces of the combined wafer T to be processed in the processing station 3. Further, the configurations of the transition device 30 and the inverting device 31 are not particularly limited.

Disposed in the processing station 3 are a wafer transfer device 40, an interface modifying apparatus 50, an internal modifying apparatus 60, a periphery removing apparatus 70, and a cleaning apparatus 80.

The wafer transfer device 40 is provided on the positive X-axis side of the transition device 30 and the inverting device 31. The wafer transfer device 40 is configured to be movable on a transfer path 41 extending in the X-axis direction to transfer the combined wafer T to/from the transition device 30, the inverting device 31, the interface modifying apparatus 50, the internal modifying apparatus 60, the periphery removing apparatus 70 and the cleaning apparatus 80.

The interface modifying apparatus 50 is configured to radiate first laser light (interface laser light such as a CO₂ laser) to an interface between the first wafer W and the second wafer S to form, in the peripheral portion We to be removed, a bonding strength reduction region Ae (see FIG. 3) in which bonding strength between the first wafer W and the second wafer S is reduced. Further, the interface modifying apparatus 50 is configured to detect a deviation amount between the first wafer W and the second wafer S in a horizontal direction in the combined wafer T as the processing target, that is, an eccentric amount between the first wafer W and the second wafer S.

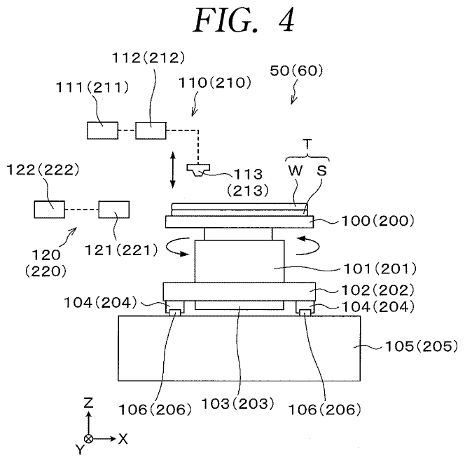

As depicted in FIG. 4, the interface modifying apparatus 50 has a chuck 100 as a substrate holder configured to hold the combined wafer T on a top surface thereof. The chuck 100 is supported by a slider table 102 with an air bearing 101 therebetween. A rotating mechanism 103 is provided on a bottom surface of the slider table 102. The rotating mechanism 103 has, for example, a motor as a driving source embedded therein. The chuck 100 is configured to be rotatable around a vertical axis by the rotating mechanism 103 via the air bearing 101. The slider table 102 is configured to be movable along a rail 106 extending in the Y-axis direction on a base 105 via a moving mechanism 104 provided on a bottom surface thereof. Further, although not particularly limited, a driving source of the moving mechanism 104 may be, by way of example, a linear motor.

A laser radiator 110 is provided above the chuck 100. The laser radiator 110 has a laser head 111, an optical system 112, and a lens 113.

The laser head 111 has a laser oscillator (not shown) configured to oscillate the interface laser light in a pulse shape. This interface laser light is a so-called pulse laser. As mentioned above, the interface laser light is, for example, CO₂ laser light, and the CO₂ laser light has a wavelength ranging from, e.g., 8.9 μm to 11 μm. Further, the laser head 111 may have other devices besides the laser oscillator, such as an amplifier.

The optical system 112 may have an optical element (not shown) configured to control the intensity and the position of the interface laser light, and an attenuator (not shown) configured to attenuate the interface laser light to adjust an output thereof. Also, the optical system 112 may be configured to be able to control the shape and the number of branches of the interface laser light.

The lens 113 is configured to radiate the interface laser light to an inside of the combined wafer T held by the chuck 100, more specifically, to the interface between the first wafer W and the second wafer S. As a result, a portion inside the combined wafer T that is irradiated with the interface laser light is modified to form the bonding strength reduction region Ae in which the bonding strength between the first wafer W and the second wafer S is reduced. Further, in the technique according to the present disclosure, the ‘interface between the first wafer W and the second wafer S’ is assumed to include interfaces and insides of the first wafer W, the device layers Dw and Ds, the bonding films Fw and Fs, and the second wafer S. In other words, as long as the bonding strength between the first wafer W and the second wafer S can be reduced, the position where the bonding strength reduction region Ae is formed is not particularly limited.

A deviation amount detector 120 is provided beside the chuck 100. The deviation amount detector 120 includes a length measurement sensor 121 and a calculator 122.

The length measurement sensor 121 is configured to measure a distance to an outer end of the combined wafer T at multiple points in a circumferential direction of the combined wafer T, appropriately, along the entire circumference of the combined wafer T, while rotating the chuck 100. The type of the length measurement sensor 121 is not particularly limited, and, for example, an interferometer or a displacement meter may be used.

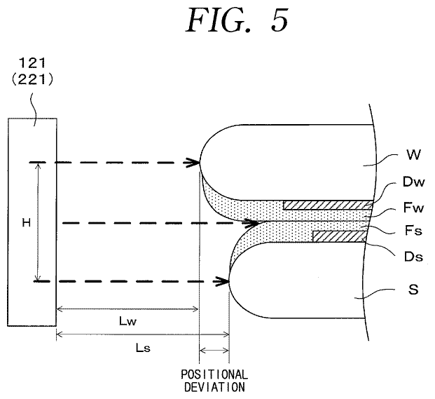

A measurement width H (a view angle of the length measurement sensor 121) of the outer end of the combined wafer T by the length measurement sensor 121 is determined to a width enabling detection of a distance Lw from the length measurement sensor 121 to the first wafer W and a distance Ls from the length measurement sensor 121 to an outer end of the second wafer S at least, as shown in FIG. 5. In addition, the ‘outer end of the first wafer W (second wafer S)’ as a measurement target appropriately refers to an apex portion, which is a peak of the chamfered portion of the peripheral portion of the first wafer W (second wafer S).

The calculator 122 calculates the deviation amount between the first wafer W and the second wafer S in the horizontal direction from a difference between the distance Lw and the distance Ls measured by the length measurement sensor 121. Also, the calculator 122 calculates the eccentric amount between the first wafer W and the second wafer S from the deviation amounts at the multiple points in the circumferential direction of the combined wafer T.

In addition, the calculator 122 may be provided separately in the interface modifying apparatus 50 as shown in FIG. 4, or may be included in a control device 90 to be described later.

Further, in the present exemplary embodiment, a distance from the length measurement sensor 121 of the deviation amount detector 120 to a rotation center of the chuck 100, and a distance from the length measurement sensor 121 to the lens 113 of the laser radiator 110 are previously stored in the control device 90, for example.

The internal modifying apparatus 60 is configured to radiate second laser light (internal laser light such as a fiber laser or a YAG laser) to an inside of the first wafer W to form a peripheral modification layer M1 (see FIG. 3) which serves as a starting point for separating the peripheral portion We and a split modification layer M2 (see FIG. 3) which serves as a starting point for breaking the peripheral portion We into smaller pieces.

The configuration of the internal modifying apparatus 60 is not particularly limited. As an example, the internal modifying apparatus 60 may have the same configuration as the interface modifying apparatus 50. That is, as shown in FIG. 4, the internal modifying apparatus 60 may include a chuck 200 configured to hold the combined wafer T on at top surface thereof, a laser radiator 210 configured to radiate the internal laser light to an inside of the first wafer W held by the chuck 200, and a deviation amount detector 220 configured to detect a deviation amount between the first wafer W and the second wafer S in the horizontal direction.

The chuck 200 as a substrate holder is configured to be rotatable around a vertical axis by a rotating mechanism 203, and may also be movable along the horizontal direction by a moving mechanism 204.

The laser radiator 210 may be equipped with a laser head 211, an optical system 212, and a lens 213. The laser head 211 may have a laser oscillator (not shown) configured to oscillate the internal laser light in a pulse shape. This internal laser light is a so-called pulse laser. As mentioned above, the internal laser light is, for example, fiber laser light or YAG laser light.

The deviation amount detector 220 includes a length measurement sensor 221 configured to measure a distance to the outer end of the combined wafer T, and a calculator 222 configured to calculate the deviation amount between the first wafer W and the second wafer S in the horizontal direction and an eccentric amount therebetween based on a measurement result of the length measurement sensor 221.

In the example shown in FIG. 4, the deviation amount detectors 120 and 220 configured to detect the deviation amount between the first wafer W and the second wafer S are provided in both the interface modifying apparatus 50 and the internal modifying apparatus 60, respectively. However, either one of these deviation amount detectors 120 and 220 may be omitted when the order of the processes on the combined wafer T in the wafer processing system 1, that is, the order of the formation of the bonding strength reduction region Ae in the interface modifying apparatus 50 and the formation of the peripheral modification layer M1 in the internal modifying apparatus 60 is determined in advance, for example.

The periphery removing apparatus 70 is configured to perform removal of the peripheral portion We of the first wafer W, that is, edge trimming, starting from the peripheral modification layer M1 formed in the internal modifying apparatus 60. A method of the edge trimming is not particularly limited. As an example, in the periphery removing apparatus 70, a blade formed in a wedge shape, for example, may be inserted into the interface between the first wafer W and the second wafer S. As another example, air may be blown or water may be jetted toward the peripheral portion We to apply an impact to the peripheral portion We.

The cleaning apparatus 80 is configured to clean the first wafer W and the second wafer S after being subjected to the edge trimming in the periphery removing apparatus 70 to thereby remove particles on these wafers. Here, a method of the cleaning is not particularly limited.

In addition, the cleaning apparatus 80 may also remove surface films remaining on the front surface Sa of the second wafer S after being subjected to the edge trimming in the periphery removing apparatus 70. The surface films to be removed include, by way of example, the bonding films Fw and Fs and the device layers Dw and Ds.

The wafer processing system 1 described above is provided with the control device 90. The control device 90 is, for example, a computer, and has a program storage (not shown). The program storage stores therein a program for controlling the processing of the combined wafer T in the wafer processing system 1. In addition, the program storage also stores therein a program for controlling the operations of a driving system such as the transfer devices and the various processing apparatuses described above to implement a wafer processing to be described later in the wafer processing system 1. The programs may have been recorded on a computer-readable recording medium, and may be installed from the recording medium into the control device 90. Further, the recording medium may be transitory or non-transitory.

So far, the various exemplary embodiments have been described. However, the present disclosure is not limited to the above-described exemplary embodiments, and various additions, omissions, replacements and modifications may be made. Further, by combining the components in the various exemplary embodiments, other exemplary embodiments may be conceived.

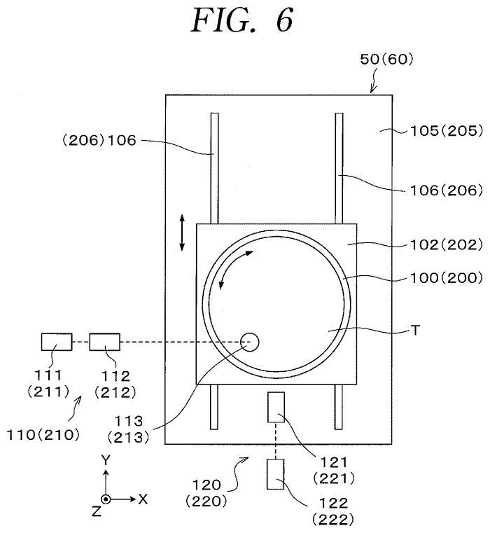

For example, in the above-described exemplary embodiment, although the length measurement sensor 121 of the deviation amount detector 120 is disposed on the negative X-axis side of the chuck 100, in other words, at a position where it faces the chuck 100 in a direction (X-axis direction) perpendicular to a moving direction (Y-axis direction) of the chuck 100 as depicted in FIG. 4, the arrangement of the length measurement sensor 121 is not limited thereto. Specifically, as shown in FIG. 6, the length measurement sensor 121 of the deviation amount detector 120 may be disposed on the negative Y-axis side of the chuck 100, in other words, at a position where it faces the chuck 100 on a movement axis (moving direction) of the chuck 100.

As will be described later, after the measurement of the distance Lw and the distance Ls (the deviation amount between the first wafer W and the second wafer S in the horizontal direction) by the length measurement sensor 121, correction of a Y-axis component of the calculated eccentric amount is performed. By disposing the length measurement sensor 121 on the negative Y-axis side of the chuck 100 as stated above, the chuck 100 is moved in the Y-axis direction and the distance between the wafer and the length measurement sensor 121 becomes constant. Thus, when checking whether the Y-axis component has been properly corrected, it is possible to more accurately check whether or not the correction of the Y-axis component is appropriate.

Further, although the above exemplary embodiment has been described for the case where the deviation amount detectors 120 and 220 include the length measurement sensors 121 and 221, such as interferometers or displacement meters, configured to detect the distance to the outer end of the combined wafer T in the interface modifying apparatus 50 and the internal modifying apparatus 60, respectively, the configuration of the deviation amount detectors may not limited thereto as long as the deviation amount between the first wafer W and the second wafer S can be detected.

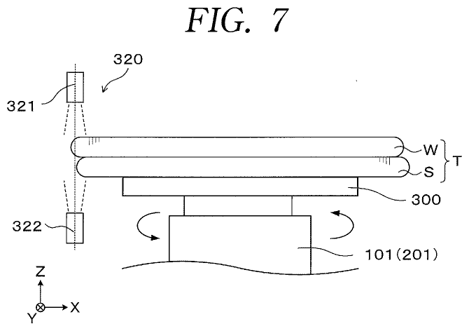

To elaborate, as shown in FIG. 7, for example, a deviation amount detector 320 may have a pair of cameras 321 and 322 configured to image the outer end of the combined wafer T held by a chuck 300 as a substrate holder from both above and below the combined wafer T. Here, it is desirable that the pair of cameras 321 and 322 are coaxially disposed in a longitudinal direction, or that a deviation amount therebetween in a horizontal direction is known. In this case, each of the outer end of the first wafer W and the outer end of the second wafer S is imaged from above and below by using the cameras 321 and 322, and a deviation amount between the first wafer W and the second wafer S may be calculated based on a positional deviation amount between the outer end of the first wafer W and the outer end of the second wafer S obtained from the taken images and the previously known positional relationship between the cameras 321 and 322.

Furthermore, in this case, it is desirable that the cameras 321 and 322 are disposed above and below the chuck 300, respectively, on the negative Y-axis side of the chuck 100, the same as the length measurement sensor 121 shown in FIG. 6. By disposing the pair of cameras 321 and 322 on the negative Y-axis side of the chuck 100 (on the movement axis of the chuck 100), imaging positions of the combined wafer T by the cameras 321 and 322 become constant, so that the deviation amount between the first wafer W and the second wafer S can be calculated more accurately.

In addition, in this case, it is desirable that the chuck 300 configured to hold the combined wafer T has a configuration capable of appropriately imaging the outer end of the second wafer S from below, particularly. Specifically, as illustrated in FIG. 7, for example, it is desirable that the chuck 300 has a smaller diameter than the combined wafer T. That is, it is desirable that the outer end of the second wafer S, which is a detection target, projects diametrically outwards from the outer end of the chuck 300.

Alternatively, there may be adopted a configuration in which the chuck 300 is made of a transparent member such as glass, and the outer end of the second wafer S is imaged through the chuck 300.

Now, a wafer processing performed by using the wafer processing system 1 configured as described above will be explained. In the present exemplary embodiment, the first wafer W and the second wafer S are bonded in advance to form the combined wafer T.

First, the cassette C accommodating therein a plurality of combined wafers T is placed on the cassette placement table 10 of the carry-in/out station 2. Then, the combined wafer T is taken out from the cassette C by the wafer transfer device 20, and transferred to the interface modifying apparatus 50 via the transition device 30 and the wafer transfer device 40.

At this time, when the combined wafer T is accommodated in the cassette C with the second wafer S facing upwards, the combined wafer T is directly transferred from the cassette C to the interface modifying apparatus 50. On the other hand, when the combined wafer T is accommodated in the cassette C with the first wafer W facing upwards, the front and rear surfaces of the combined wafer T are inverted by the inverting device 31, and the combined wafer T is then transferred to the interface modifying apparatus 50.

That is, the chuck 100 of the interface modifying apparatus 50 attracts and holds the entire rear surface Wb of the first wafer W in the state that the second wafer S is positioned on the upper side and the first wafer W is positioned on the lower side.

In the interface modifying apparatus 50, first, a deviation amount between the first wafer W and the second wafer S forming the combined wafer T held by the chuck 100 (an eccentric amount between the first wafer W and the second wafer S) in the horizontal direction is detected by using the deviation amount detector 120 (process St1 in FIG. 8).

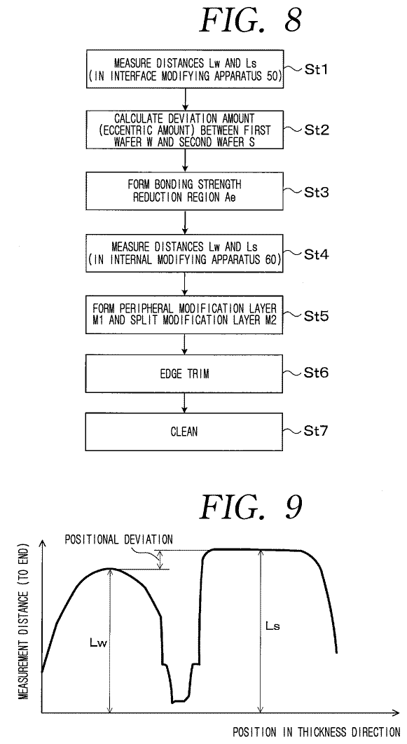

To elaborate, the distance Lw between the length measurement sensor 121 of the deviation amount detector 120 and the outer end of the first wafer W, and the distance Ls (see FIG. 5) between the length measurement sensor 121 and the outer end of the second wafer S are first measured. For example, as illustrated in FIG. 9, a measurement result by the length measurement sensor 121 is acquired as a relationship between a distance (vertical axis) from the length measurement sensor 121 to the outer end of the combined wafer T and a position (horizontal axis) of the combined wafer T in a thickness direction, which is the direction of the measurement width by the length measurement sensor 121. Data including the distance from the length measurement sensor 121 to the outer end of the combined wafer T is acquired at the multiple points of the combined wafer T in the circumferential direction, desirably, from the entire circumference of the combined wafer T. Additionally, the measurement results acquired by the length measurement sensor 121 are outputted to the calculator 122.

Once the measurement results by the length measurement sensor 121 are obtained, the calculator 122 of the deviation amount detector 120 calculates the positions of the first wafer W and the second wafer S on the chuck 100 based on the distances Lw and Ls obtained from the measurement results.

Further, the calculator 122 calculates a deviation amount between the first wafer W and the second wafer S in the horizontal direction from a difference between the obtained distances Lw and Ls. In addition, an eccentric amount between the first wafer W and the second wafer S (a deviation amount between the center of the first wafer W and the center of the second wafer S) is calculated from the deviation amounts calculated at the multiple potions in the circumferential direction of the combined wafer T (process St2 in FIG. 8). The calculated eccentric amount is outputted to the control device 90.

The control device 90 acquires an eccentric amount between the chuck 100 and the second wafer S, that is, a deviation amount between the rotation center of the chuck 100 and the center of the second wafer S. The eccentric amount between the chuck 100 and the second wafer S may be acquired by using the measurement result by the length measurement sensor 121, or may be acquired by using a non-illustrated eccentric amount detector (for example, a camera or the like).

When acquiring the eccentric amount between the chuck 100 and the second wafer S by using the measurement result from the length measurement sensor 121, the eccentric amount between the chuck 100 and the second wafer S may be calculated based on, for example, a positional relationship between the length measurement sensor 121 and the rotation center of the chuck 100 previously stored in the control device 90 and the distance Ls acquired in the process St1, that is, the position of the second wafer S on the chuck 100.

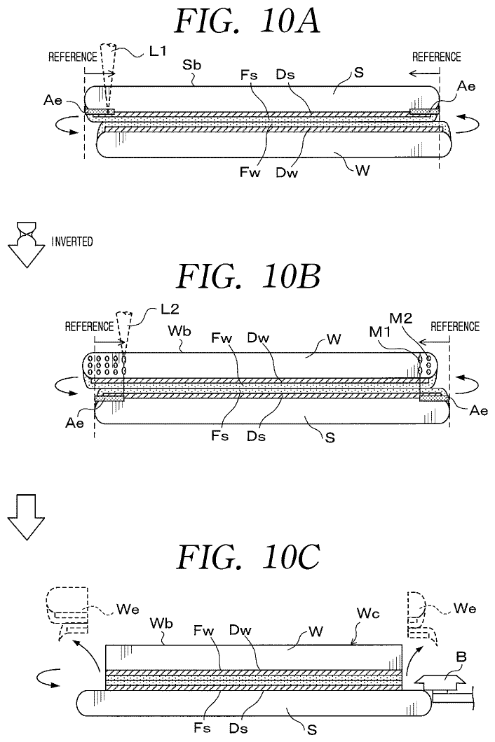

Once the eccentric amount between the first wafer W and the second wafer S is calculated, the interface laser light L1 is then radiated in a pulse shape from the laser radiator 110 to a preset irradiation area to thereby modify the interface (in the shown example, the interface between the second wafer S and the bonding film Fs) between the first wafer W and the second wafer S, as illustrated in FIG. 3 and FIG. 10A. In the present exemplary embodiment, the interface laser light L1 is radiated from the rear surface Sb side of the second wafer S toward the combined wafer T. Further, in the present exemplary embodiment, ‘modification of the interface’ is assumed to include amorphization of the device layers Dw and Ds and the bonding films Fw and Fs at the irradiation position of the interface laser light L1, separation of the first wafer W and the second wafer S, and so forth.

The irradiation area of the interface laser light L1 is set as an annular area having a required width in a diametrical direction with respect to the outer end of the second wafer S, as shown as an example in FIG. 10A. The width of the irradiation area of the interface laser light L1 in the diametrical direction is set to a width enabling appropriate removal of the peripheral portion We of the first wafer W, which is a target to be removed. In other words, in the edge trimming of the first wafer W according to the present exemplary embodiment, the bonding strength reduction region Ae is formed at the required position with respect to the outer end of the second wafer S. In this exemplary embodiment, since the position of the outer end of the second wafer S, which serves as a reference for the irradiation area of the interface laser light L1, is acquired in advance based on the measurement result (distance Ls) by the length measurement sensor 121 of the above-described deviation amount detector 120, the irradiation area of the interface laser light L1 can be appropriately detected. In addition, in the present exemplary embodiment, since the positional relationship between the length measurement sensor 121 and the lens 113 of the laser radiator 110 is stored in advance as stated above, the irradiation position of the interface laser light L1 can be appropriately set within an irradiation area based on the positional relationship and the measurement result (distance Ls) by the length measurement sensor 121.

Furthermore, the interface laser light L1 is radiated from above the second wafer S to the irradiation area of the interface laser light L1 while rotating the chuck 100 (combined wafer T). At this time, when there is a deviation between the rotation center of the chuck 100 and the center of the second wafer S, there is a risk that the interface laser light L1 may not be properly radiated to the determined irradiation area. Also, a deviation between the first wafer W and the second wafer S in the horizontal direction, if any, may also raise a risk that the interface laser light L1 may not be properly radiated.

In view of this, in the interface modifying apparatus 50 according to the present exemplary embodiment, the interface laser light L1 is radiated while performing correction of eccentricity in consideration of the eccentric amount between the first wafer W and the second wafer S acquired in the process St2 and the eccentric amount between the second wafer S and the chuck 100. That is, while rotating the chuck 100 (combined wafer T) and moving the chuck 100 in the horizontal direction along the Y-axis direction to correct the calculated eccentric amounts, the interface laser light L1 is radiated to the interface between the first wafer W and the second wafer S.

In the interface modifying apparatus 50, by modifying the irradiation position of the interface laser light L1 at the interface between the first wafer W and the second wafer S in this way, the bonding strength reduction region Ae in which the bonding strength between the first wafer W and the second wafer S is reduced is formed (process St3 in FIG. 8). In the edge trimming to be described later, the peripheral portion We of the first wafer W, which is the target to be removed, is removed. The presence of this bonding strength reduction region Ae enables appropriate removal of the peripheral portion We.

In addition, in the formation of the bonding strength reduction region Ae in the interface modifying apparatus 50 according to the present exemplary embodiment, the chuck 100 is moved horizontally along the Y-axis direction to correct the eccentric amount between the first wafer W and the second wafer S as well as the eccentric amount between the chuck 100 and the second wafer S. Accordingly, even in the case where there is misalignment between the first wafer W and the second wafer S as well as in the case where the combined wafer T (first wafer W) is held by the chuck 100 eccentrically with respect to the chuck 100, the bonding strength reduction region Ae can be appropriately formed at the required irradiation area of the interface laser light L1.

The combined wafer T in which the bonding strength reduction region Ae is formed at the interface between the first wafer W and the second wafer S is then transferred to the inverting device 31 by the wafer transfer device 40. In the inverting device 31, the front and rear surfaces of the combined wafer T are inverted, and, as a result, the combined wafer T is positioned with the first wafer W facing upwards.

The combined wafer T, whose front and rear surfaces have been inverted, is then transferred to the internal modifying apparatus 60 by the wafer transfer device 40. The chuck 200 of the internal modifying apparatus 60 attracts and holds the entire rear surface Sb of the second wafer S in the state that the first wafer W is disposed on the upper side and the second wafer S is disposed on the lower side.

In the internal modifying apparatus 60, first, the position of the combined wafer T held by the chuck 200, that is, the distances Lw and Ls between the length measurement sensor 221 and the first and second wafers W and S are measured by using the length measurement sensor 221 of the deviation amount detector 220 (process St4 in FIG. 8). The measurement results of the length measurement sensor 221 are outputted to the calculator 222.

In addition, the control device 90 acquires an eccentric amount between the chuck 200 and the first wafer W, that is, a deviation amount between the rotation center of the chuck 200 and the center of the first wafer W. The eccentric amount between the chuck 200 and the first wafer W may be acquired by using the measurement result obtained by the length measurement sensor 221, or may be acquired by using a non-illustrated eccentric amount detector (for example, a camera, or the like).

When acquiring the eccentric amount between the chuck 200 and the first wafer W by using the measurement results from the length measurement sensor 221, the eccentric amount between the chuck 200 and the first wafer W may be calculated based on, for example, a positional relationship between the length measurement sensor 221 and the chuck 200 previously stored in the control device 90 and the distance Lw acquired by the length measurement sensor 221, that is, the position of the first wafer W on the chuck 200.

Next, internal laser light L2 is radiated from the laser radiator 210 to a predetermined irradiation position of the internal laser light L2 to form a peripheral modification layer M1 and a split modification layer M2 inside the first wafer W in sequence, as shown in FIG. 3 and FIG. 10B (process St5 in FIG. 8). In the present exemplary embodiment, the internal laser light L2 is radiated from the rear surface Wb side of the first wafer W toward the combined wafer T. The peripheral modification layer M1 serves as a starting point for removing the peripheral portion We in the edge trimming to be described later. The split modification layer M2 serves as a starting point for breaking the to-be-removed peripheral portion We into smaller pieces. Further, in the drawings to be used in the following description, illustration of the split modification layer M2 may be omitted in order to avoid complicating the illustration.

The irradiation position of the internal laser light L2, that is, the formation position of the peripheral modification layer M1 is set to be slightly inside an inner end of the bonding strength reduction region Ae formed in the process St3 in the diametrical direction with respect to the outer end of the second wafer S, for example. In other words, in the edge trimming of the first wafer W according to the present exemplary embodiment, the peripheral modification layer M1 is formed at a required position with respect to the outer end of the second wafer S. In the present exemplary embodiment, the position of the outer end of the second wafer S, which serves as a reference for the formation position of the peripheral modification layer M1, is acquired in advance based on the measurement result (distance Ls) by the length measurement sensor 221 described above. Further, a positional relationship between the length measurement sensor 221 and the lens 213 of the laser radiator 210 is stored in advance. Thus, the irradiation position of the internal laser light L2 can be appropriately set to the required position.

Additionally, the internal laser light L2 is radiated to the irradiation position of the internal laser light L2 while rotating the chuck 200 (combined wafer T). At this time, when there is a deviation between the rotation center of the chuck 200 and the center of the first wafer W, there is a risk that the internal laser light L2 may not be properly radiated to the determined irradiation position. Also, a deviation between the first wafer W and the second wafer S in the horizontal direction, if any, may also raise a risk that the internal laser light L2 may not be properly radiated.

In view of this, in the internal modifying apparatus 60 according to the present exemplary embodiment, the internal laser light L2 is radiated while performing correction of eccentricity, in consideration of the eccentric amount between the first wafer W and the second wafer S calculated in the process St2 and the eccentric amount between the first wafer W and the chuck 200 calculated in the process St4. That is, the internal laser light L2 is radiated to the inside of the first wafer W while rotating the chuck 200 (combined wafer T) and moving the chuck 200 horizontally along the Y-axis direction to correct the calculated eccentric amounts.

In the internal modifying apparatus 60, the chuck 200 is moved horizontally along the Y-axis direction correct the eccentric amount between the first wafer W and the second wafer S in addition to the eccentric amount between the chuck 200 and the first wafer W. Accordingly, even in the case where there is misalignment between the first wafer W and the second wafer S as well as in the case where the combined wafer T is eccentrically held by the chuck 200, the peripheral modification layer M1 can be appropriately formed at the required position.

The combined wafer T having the peripheral modification layer M1 and the split modification layer M2 formed inside the first wafer W is then transferred to the periphery removing apparatus 70 by the wafer transfer device 40. In the periphery removing apparatus 70, the removal of the peripheral portion We of the first wafer W, that is, the edge trimming is performed, as shown in FIG. 10C (process St6 in FIG. 8).

In the removal of the peripheral portion We, a blade B formed in a wedge shape may be inserted into the interface between the first wafer W and the second wafer S forming the combined wafer T, as illustrated in FIG. 10C, for example.

The insertion position of the blade B with respect to the interface between the first wafer W and the second wafer S may be determined based on, for example, the measurement result in the process St1. To be specific, as shown in FIG. 9, the measurement result in the process St1 is acquired as data indicating a relationship between the distance from the length measurement sensor 121 of the deviation amount detector 120 to the outer end of the combined wafer T and the position of the combined wafer T in the thickness direction. In other words, from the measurement result in the process St1, an end position of the combined wafer T (outline of the outer end of the combined wafer T) in the thickness direction of the combined wafer T is obtained as data, and based on this data, the position of a bonding interface between the first wafer W and the second wafer S may be detected.

In the periphery removing apparatus 70, the insertion position of the blade B may be appropriately determined based on the position of the bonding interface between the first wafer W and the second wafer S detected in this way.

If the blade B is inserted into the interface between the first wafer W and the second wafer S, the peripheral portion We of the first wafer W is separated from the central portion Wc of the first wafer W, starting from the peripheral modification layer M1, and is completely separated from the second wafer S, starting from the bonding strength reduction region Ae. At this time, the peripheral portion We being removed is broken into smaller pieces, starting from the split modification layer M2.

The combined wafer T from which the peripheral portion We of the first wafer W has been removed is then transferred to the cleaning apparatus 80 by the wafer transfer device 40. In the cleaning apparatus 80, the first wafer W from which the peripheral portion We has been removed and/or the second wafer S are cleaned (process St7 in FIG. 8).

A cleaning method by the cleaning apparatus 80 is not particularly limited. For example, the first wafer W and the second wafer S may be scrub-cleaned by bringing a brush into contact with the first wafer W and the second wafer S. Further, a pressurized cleaning liquid may be used to clean the first wafer W and the second wafer S.

Afterwards, the combined wafer T after being subjected to all the required processes is transferred to the transition device 30 by the wafer transfer device 40, and is then transferred to the cassette C on the cassette placement table 10 by the wafer transfer device 20. In this way, the series of processes of the wafer processing in the wafer processing system 1 are completed.

In addition, for the combined wafer T after being subjected to the edge trimming of the first wafer W, it may be inspected whether the edge trimming has been appropriately performed, that is, whether the peripheral portion We has been removed from the first wafer W by the required trim width (inspection of completeness). An inspection device (not shown) for inspecting the completeness of the edge trimming may be integrated with, for example, the periphery removing apparatus 70, or may be independently disposed outside the periphery removing apparatus 70. Further, the inspection device (not shown) may be disposed inside or outside the wafer processing system 1.

In the above-described the edge trimming method according to the present exemplary embodiment, in the interface modifying apparatus 50 configured to form the bonding strength reduction region Ae and the internal modifying apparatus 60 configured to form the peripheral modification layer M1 and the split modification layer M2, the deviation amount detectors 120 and 220 equipped with the length measurement sensors 121 and 221 are disposed beside the chucks 100 and 200 configured to hold the combined wafer T, respectively.

Conventionally, when detecting the position of the combined wafer T from above the chuck by using a vision system such as a camera, the end position of the combined wafer T may not be accurately detected due to the film quality, the film contamination, and the like of the first wafer W and the second wafer S, so it has been difficult to detect the deviation amount between the first wafer W and the second wafer S.

According to the present exemplary embodiment, however, since the length measurement sensors 121 and 221 such as interferometers or displacement meters are used, not only the position of the combined wafer T on the chucks 100 and 200 can be appropriately detected regardless of the aforementioned film quality, the film contamination, and the like of the first wafer W and the second wafer S, the deviation amount (eccentric amount) between the first wafer W and the second wafer S can also be appropriately calculated.

Further, in the wafer processing system 1 according to the above-described exemplary embodiment, the position of the combined wafer T on the chucks 100 and 200 is appropriately detected and the irradiation position of the laser light is aligned to the required position only by using the deviation amount detectors 120 and 220 including the length measurement sensors 121 and 221 disposed in the interface modifying apparatus 50 and the internal modifying apparatus 60, respectively.

However, instead of determining the irradiation position of the laser light by using only the deviation amount detectors 120 and 220, each of the interface modifying apparatus 50 and the internal modifying apparatus 60 may be further equipped with an imaging mechanism (for example, a camera) configured to detect the position of the combined wafer T from above the chucks 100 and 200, respectively. In this case, the interface modifying apparatus 50 and the internal modifying apparatus 60 may determine the irradiation position of the laser light by detecting the end position of the combined wafer T using the imaging mechanisms, and may detect the deviation amount between the first wafer W and the second wafer S by using the deviation amount detectors 120 and 220, respectively. Also, in this case, it is desirable that positional relationships between the imaging mechanisms and the length measurement sensors 121 and 221 of the deviation amount detectors 120 and 220, respectively, are previously stored in the control device 90.

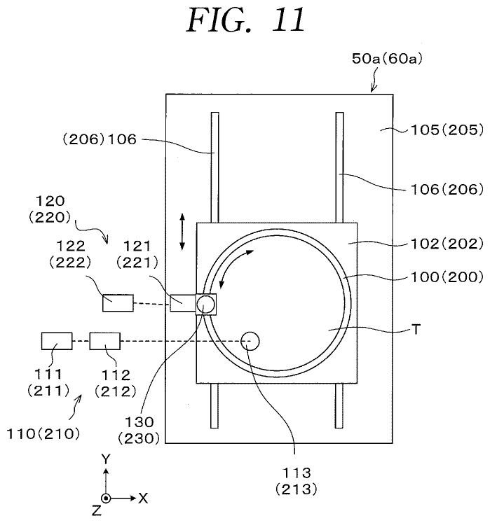

FIG. 11 is a plan view schematically illustrating configurations of an interface modifying apparatus 50a and an internal modifying apparatus 60a equipped with imaging mechanisms 130 and 230, respectively, according to another exemplary embodiment. In the following description, in the configurations of the interface modifying apparatus 50a and the internal modifying apparatus 60a, parts having substantially the same functions and configurations as those of the interface modifying apparatus 50 and the internal modifying apparatus 60 shown in FIG. 4 will be assigned same reference numerals, and a detailed description thereof will be omitted. In addition, since the configurations of the interface modifying apparatus 50a and the internal modifying apparatus 60a are identical as illustrated in FIG. 11, the configuration of the interface modifying apparatus 50a will be explained as a representative example in the following description.

The interface modifying apparatus 50a includes a chuck 100 configured to hold the combined wafer T on a top surface thereof, a laser radiator 110 disposed above the chuck 100, and a deviation amount detector 120 disposed beside the chuck 100.

In addition to the above-described configuration of the interface modifying apparatus 50 shown in FIG. 4, the interface modifying apparatus 50a is equipped with the imaging mechanism 130 configured to image the outer end of the combined wafer T held by the chuck 100. The imaging mechanism 130 is configured to be able to image a detection target position of the outer end of the combined wafer T to be detected by the deviation amount detector 120 from above. That is, the imaging mechanism 130 is disposed above the chuck 100 at the same position as the length measurement sensor 121 of the deviation amount detector 120 in the Y-axis direction and on the positive X-axis side of the length measurement sensor 121. The imaging mechanism 130 may be configured to be movable up and down by a non-illustrated elevating mechanism. Further, it is desirable that a positional relationship between the imaging mechanism 130 and the lens 113 of the laser radiator 110 is stored in the control device 90 in advance.

The imaging mechanism 130 includes one or more cameras selected from, for example, a macro camera and a micro camera, and is configured to image the outer end of the combined wafer T held by the chuck 100. The imaging mechanism 130 has, for example, a coaxial lens, and serves to radiate light, for example, infrared light (IR), which has penetrability for at least the first wafer W and the second wafer S and receive reflection light from an object.

In the interface modifying apparatus 50a, while rotating the chuck 100, outer end of the combined wafer T (in the example of the above-described exemplary embodiment, the second wafer S disposed on the upper side on the chuck 100) is imaged by the imaging mechanism 130 in 360 degrees in a circumferential direction thereof. The obtained image is outputted from the imaging mechanism 130 to the control device 90.

The control device 90 calculates an eccentric amount between the rotation center of the chuck 100 and the center of the second wafer S from the image from the imaging mechanism 130. Then, based on the calculated eccentric amount, the control device 90 moves the chuck 100 in the Y-axis direction to correct a Y-axis component of this eccentric amount.

Additionally, the control device 90 sets an irradiation area of the interface laser light L1 for forming the bonding strength reduction region Ae from the image obtained by the imaging mechanism 130. The irradiation area of the interface laser light L1 is set as, for example, an annular area having a required width in a diametrical direction with respect to the outer end of the second wafer S detected from the image taken by the imaging mechanism 130.

Then, in the interface modifying apparatus 50, after a deviation amount between the first wafer W and the second wafer S is detected by using the deviation amount detector 120, the interface laser light L1 is radiated from the laser radiator 110 to the determined irradiation area to form the bonding strength reduction region Ae.

At this time, according to the present exemplary embodiment, since the positional relationship between the imaging mechanism 130 and the lens 113 of the laser radiator 110 is stored in the control device 90 in advance as described above, an irradiation position of the interface laser light L1 by the laser radiator 110 can be appropriately set within the predetermined irradiation area.

As stated above, in the wafer processing system 1 according to the present exemplary embodiment, the imaging mechanism 130 (230) configured to detect the position of the combined wafer T (the first wafer W and/or the second wafer S) on the chuck and the deviation amount detector 120 (220) may be independently provided, as in the interface modifying apparatus 50a (the internal modifying apparatus 60a) shown in FIG. 11.

Accordingly, as compared to the case where the irradiation position of the laser light is determined by using only the deviation amount detectors 120 and 220, the bonding strength reduction region Ae and the peripheral modification layer M1 can be formed more appropriately, and a throughput regarding the formation of the bonding strength reduction region Ae and the peripheral modification layer M1 can be improved.

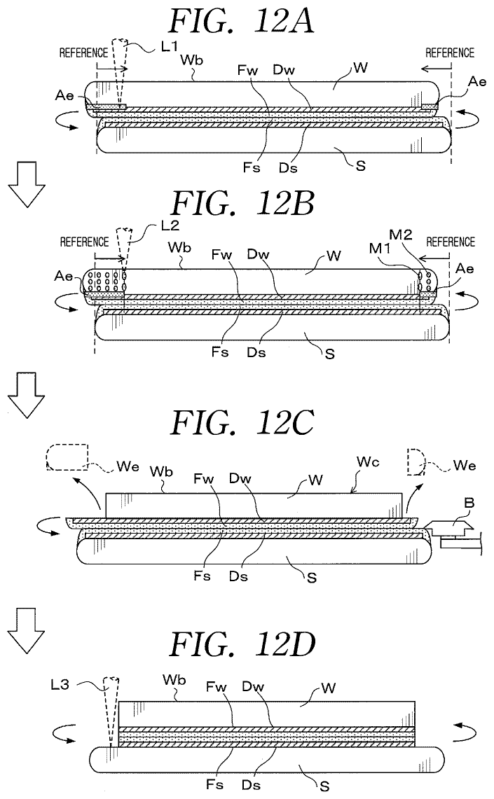

Furthermore, in the above-described exemplary embodiment, in forming the bonding strength reduction region Ae in the interface modifying apparatus 50, the interface laser light L1 is radiated from the second wafer S side, as illustrated in FIG. 10A. However, the interface laser light L1 may be radiated from the first wafer W side. In this case, as shown as an example in FIG. 12A, the bonding strength reduction region Ae is formed at the interface between the first wafer W and the bonding film Fw. Afterwards, the internal laser light L2 is radiated from the first wafer W side to form the peripheral modification layer M1 and the split modification layer M2 inside the first wafer W, as shown in FIG. 12B, and the peripheral portion We is removed starting from the peripheral modification layer M1 and the bonding strength reduction region Ae, as shown in FIG. 12C.

In addition, by radiating a cleaning laser L3 (for example, a femtosecond laser) to the combined wafer T from which the peripheral portion We of the first wafer W has been removed, the surface films (the bonding films Fw and Fw and the device layers Dw and Ds) remaining on the front surface Sa of the second wafer S may be removed, as shown in FIG. 12D. Alternatively, the surface films may be removed by, for example, blasting or etching.

Moreover, in the above-described exemplary embodiment, although the formation of the bonding strength reduction region Ae (process St3) and the formation of the peripheral modification layer M1 and the split modification layer M2 (process St5) in the combined wafer T are performed in this order, the order of forming them is not particularly limited.

That is, the bonding strength reduction region Ae may be formed at the interface between first wafer W and the second wafer S in the interface modifying apparatus 50 after forming the peripheral modification layer M1 and the split modification layer M2 inside the first wafer W in the internal modifying apparatus 60.

In this case, the detection of the deviation amount between the first wafer W and the second wafer S in the horizontal direction (that is, the eccentric amount between the first wafer W and the second wafer S) (process St1) may be performed by the deviation amount detector 220 of the internal modifying apparatus 60 instead of the deviation amount detector 120 of the interface modifying apparatus 50.

Further, in the above-described exemplary embodiment, although the bonding strength reduction region Ae for lowering the bonding strength between the first wafer W and the second wafer S is formed (process St3), the formation of the bonding strength reduction region Ae may be appropriately omitted.

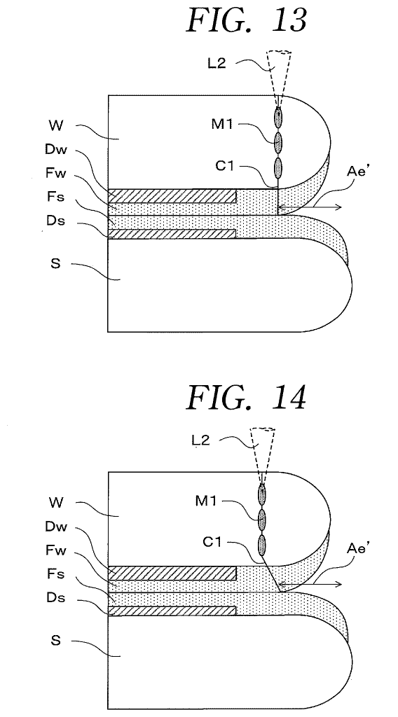

Specifically, the peripheral modification layer M1, which serves as a starting point for the removal of the peripheral portion We, is formed to correspond to a chamfered portion of the outer end of the first wafer W, as shown in FIG. 13. In other words, a non-bonding region Ae′ in which the first wafer W and the second wafer S is not substantially bonded, which exists at the bonding interface between the first wafer W and the second wafer S due to chamfered portions formed at peripheral portions of both wafers, is regarded as the bonding strength reduction region Ae, and edge trimming of the first wafer W may be performed by forming the peripheral modification layer M1 to correspond to inner ends of these chamfered portions in the diametrical direction.

The chamfered portions (non-bonding region Ae′) of the first wafer W and the second wafer S, which is regarded as the bonding strength reduction region Ae, may be detected based on a measurement result obtained by the length measurement sensor 121 of the deviation amount detector 120 shown in FIG. 5 and FIG. 9 (in the example shown in FIG. 5, a measurement result obtained by measurement light at the center among three measurement lights emitted from the length measurement sensor 121). In other words, the irradiation position of the interface laser light L2, that is, the formation position of the peripheral modification layer M1 may be determined based on the position of an inner end of the non-bonding region Ae' in the diametrical direction that is detected from the measurement result obtained by the length measurement sensor 121.

According to the example shown in FIG. 13, the peripheral portion We of the first wafer W is separated from the central portion Wc of the first wafer W starting from the peripheral modification layer M1. Further, since the first wafer W and the second wafer S are not substantially bonded at a diametrically outside of the formation position of the peripheral modification layer M1 due to the presence of the chamfered portions, the peripheral portion We may be appropriately removed from the second wafer S.

Additionally, according to the present example, since there is no need to form the bonding strength reduction region Ae in the interface modifying apparatus 50 when performing the edge trimming of the first wafer W, a throughput regarding the edge trimming may be significantly improved.

Furthermore, as shown in FIG. 13, when the peripheral modification layer M1 is formed by the radiation of the internal laser light L2, a crack C1 develops, inside the first wafer W, from the peripheral modification layer M1 in a thickness direction of the first wafer W. In the edge trimming in the peripheral removing apparatus 70, the peripheral portion We is separated from the central portion Wc starting from, more specifically, the peripheral modification layer M1 and the crack C1.

In this regard, the irradiation position of the internal laser light L2, that is, the formation position of the peripheral modification layer M1 may be controlled to be slightly diametrically inside the inner end of the non-bonding region Ae′ in the diametrical direction, as shown in FIG. 14. In this case, by allowing the crack C1 to develop obliquely from the peripheral modification layer M1 toward the inner end of the non-bonding region Ae′ in the diametrical direction, the peripheral portion We can be appropriately removed from the combined wafer T.

In addition, this method of controlling the extension direction of the crack C1 from the peripheral modification layer M1 can also be applied when forming the bonding strength reduction region Ae as shown in FIG. 10A to FIG. 10C or FIG. 12A to FIG. 12D. That is, in the example shown in FIG. 10A to FIG. 10C or FIG. 12A to FIG. 12D, the formation position of the peripheral modification layer M1 is controlled to approximately coincide with the inner end of the bonding strength reduction region Ae in the diametrical direction. However, as in the method shown in FIG. 14, the peripheral modification layer M1 may be formed slightly inside the inner end of the bonding strength reduction region Ae in the diametrical direction, while allowing the crack C1 to develop obliquely.

In addition, in the above-described exemplary embodiment, although the deviation amount (eccentric amount) between the first wafer W and the second wafer S in the horizontal direction is acquired by using the deviation amount detector 120 of the interface modifying apparatus 50 or the deviation amount detector 220 of the internal modifying apparatus 60, the location where the deviation amount (eccentric amount) is acquired is not limited thereto.

For example, a deviation amount detecting device (not shown) may be provided in the wafer processing system 1, separately from the interface modifying apparatus 50 and the internal modifying apparatus 60, and the deviation amount (eccentric amount) between the first wafer W and the second wafer S may be acquired in this deviation amount detecting device.

As another example, the deviation amount (eccentric amount) between the first wafer W and the second wafer S may be previously acquired in a bonding device (not shown) provided outside the wafer processing system 1 to bond the first wafer W and the second wafer S, and data of this deviation amount (eccentric amount) may be outputted from this external device to the control device 90 when the combined wafer T is carried into the wafer processing system 1.

Additionally, when acquiring the data of the deviation amount from the external device outside the wafer processing system 1 as described above, imaging mechanisms (the imaging mechanism 130 and 230) configured to detect the outer end of the combined wafer T, which is a reference for determining the irradiation positions of the interface laser light L1 and the internal laser light L2, need to be provided in the interface modifying apparatus configured to form the bonding strength reduction region Ae and the internal modifying apparatus configured to form the peripheral modification layer M1 and the split modification layer M2.

### Edge Trimming Method of First Wafer According to Another Exemplary Embodiment

Now, an edge trimming method of the first wafer W according to another exemplary embodiment will be described with reference to the accompanying drawings. In the edge trimming method according to this exemplary embodiment, the irradiation positions of the interface laser light L1 and the internal laser light L2 are aligned with respect to the outer end of the first wafer W instead of the outer end of the second wafer S. Further, in the following description, a detailed description of processes substantially the same as those of the above-described exemplary embodiment based on the outer end of the second wafer S will be omitted.

First, the cassette C accommodating therein a plurality of combined wafers T is placed on the cassette placement table 10 of the carry-in/out station 2. Then, the combined wafer T in the cassette C is taken out by the wafer transfer device 20, and transferred to the interface modifying apparatus 50 via the transition device 30 and the wafer transfer device 40.

At this time, when the combined wafer T is accommodated in the cassette C with the second wafer S facing upwards, the combined wafer T is directly transferred from the cassette C to the interface modifying apparatus 50. On the other hand, when the combined wafer T is accommodated in the cassette C with the first wafer W facing upwards, the combined wafer T is transferred to the interface modifying apparatus 50 after the front and rear surfaces of the combined wafer T are inverted by the inverting device 31.

That is, the chuck 100 of the interface modifying apparatus 50 attracts and holds the entire rear surface Wb of the first wafer W in the state that the second wafer S is positioned on the upper side and the first wafer W is positioned on the lower side.

In the interface modifying apparatus 50, first, a deviation amount in a horizontal direction between the first wafer W and the second wafer S (an eccentric amount between the first wafer W and the second wafer S) forming the combined wafer T held by the chuck 100 is detected by using the deviation amount detector 120 (process St1 in FIG. 8). A method of detecting the deviation amount between the first wafer W and the second wafer S in the horizontal direction is the same as that in the above-described exemplary embodiment. A measurement result obtained by the length measurement sensor 121 is outputted to the calculator 122.

The calculator 122 calculates the positions of the outer ends of the first wafer W and the second wafer S on the chuck 100 based on the measurement result in the process St1.

Further, the calculator 122 calculates the deviation amount between the first wafer W and the second wafer S in the horizontal direction from a difference between the acquired distances Lw and Ls, and also calculates the eccentric amount between the first wafer W and the second wafer S (process St2 in FIG. 8). The calculated eccentric amount is outputted to the control device 90.

The control device 90 calculates an eccentric amount between the chuck 100 and the second wafer S, that is, a deviation amount between the rotation center of the chuck 100 and the center of the second wafer S.

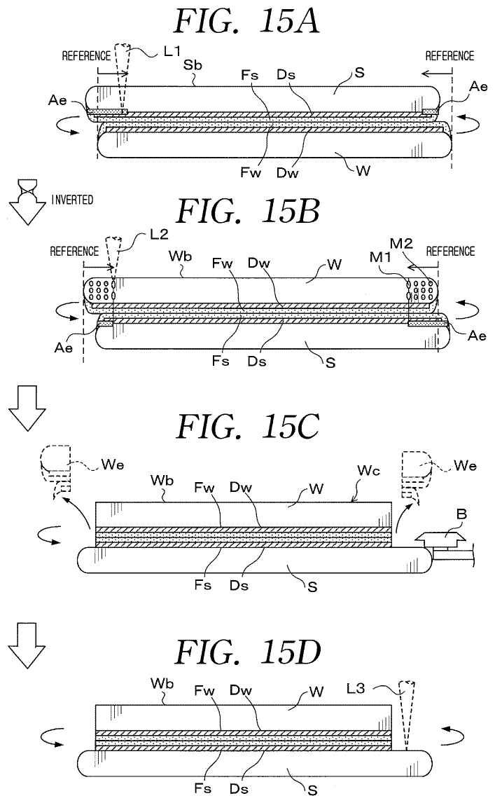

Next, the interface laser light L1 is radiated in a pulse shape from the laser radiator 110 to a preset irradiation area to form the bonding strength reduction region Ae at the interface between the first wafer W and the second wafer S (in the shown example, at the interface between the second wafer S and the bonding film Fs), as illustrated in FIG. 3 and FIG. 15A (process St3 in FIG. 8). As an example, the interface laser light L1 is radiated from the second wafer S side toward the combined wafer T.

In the present exemplary embodiment, the irradiation area of the interface laser light L1 is determined as an annular area having a required width in a diametrical direction with respect to the outer end of the first wafer W, as shown in FIG. 15A. The width of the irradiation area of the interface laser light L1 in the diametrical direction is set to a width that enables appropriate removal of the to-be-removed peripheral portion We of the first wafer W. In other words, in the edge trimming of the first wafer W according to the present exemplary embodiment, the bonding strength reduction region Ae is formed at a required position with respect to the outer end of the first wafer W. In this exemplary embodiment, since the position of the outer end of the first wafer W, which serves as a reference for the irradiation area of the interface laser light L1, is determined in advance based on the measurement result (distance Lw) obtained by the length measurement sensor 121 of the above-described deviation amount detector 120, the irradiation area of the interface laser light L1 can be appropriately detected. Further, in the present exemplary embodiment, since the positional relationship between the length measurement sensor 121 and the lens 113 of the laser radiator 110 is stored in advance as stated above, the irradiation position of the interface laser light L1 can be appropriately set within the irradiation area based on this positional relationship and the measurement result (distance Lw) obtained by the length measurement sensor 121.

Furthermore, in the present exemplary embodiment, the outer ends of the first wafer W and the second wafer S are independently detected by using the deviation amount detector 120 including the length measurement sensor 121 provided beside the chuck 100 as stated above. For this reason, as compared to a conventional case where a deviation amount of the second wafer S is viewed from above the combined wafer T, for example, the alignment of the irradiation position of the interface laser light L1 with respect to the outer end of the second wafer S can be appropriately performed.

In addition, the radiation of the interface laser light L1 to the combined wafer T may be performed from the second wafer S side as described above, or may be performed from the first wafer W side.

The combined wafer T having the bonding strength reduction region Ae formed at the interface between the first wafer W and the second wafer S is then transferred to the inverting device 31 by the wafer transfer device 40. In the inverting device 31, the front and rear surfaces of the combined wafer T are inverted, allowing the first wafer W to face upwards.

The combined wafer T, whose front and rear surfaces have been inverted, is then transferred to the internal modifying apparatus 60 by the wafer transfer device 40. The chuck 200 of the internal modifying apparatus 60 attracts and holds the entire rear surface Sb of the second wafer S in the state that the first wafer W is positioned on the upper side and the second wafer S is positioned on the lower side.

In the internal modifying apparatus 60, first, the position of the combined wafer T held by the chuck 200 is detected by using the length measurement sensor 221 of the deviation amount detector 220 (process St4 in FIG. 8). A measurement result obtained by the length measurement sensor 221 is outputted to the calculator 222. Further, an eccentric amount calculated by the calculator 222 is outputted to the control device 90.

Additionally, the control device 90 acquires an eccentric amount between the chuck 200 and the second wafer S, that is, a deviation amount between the rotation center of the chuck 200 and the center of the second wafer S.

Next, the internal laser light L2 is radiated from the laser radiator 210 to a predetermined irradiation position of the internal laser light L2 to form the peripheral modification layer M1 and the split modification layer M2 inside the first wafer W, as shown in FIG. 3 and FIG. 15B (process St5 in FIG. 8). In one example, the internal laser light L2 is radiated from the first wafer W side toward the combined wafer T.

The irradiation position of the internal laser light L2, that is, the formation position of the peripheral modification layer M1 is set to be slightly diametrically inside the inner end of the bonding strength reduction region Ae formed in the process St3 in the diametrical direction with respect to the outer end of the first wafer W, for example. In other words, in the edge trimming of the first wafer W according to the present exemplary embodiment, the peripheral modification layer M1 is formed at a required position with respect to the outer end of the first wafer W. In this exemplary embodiment, since the position of the outer end of the first wafer W, which serves as a reference for the formation position of the peripheral modification layer M1, is previously acquired based on the measurement result (distance Lw) by the length measurement sensor 221 as described above, and since the positional relationship between the length measurement sensor 221 and the lens 213 of the laser radiator 210 is stored in advance, the irradiation position of the internal laser light L2 can be appropriately aligned to a required position.

The combined wafer T having the peripheral modification layer M1 and the split modification layer M2 formed inside the first wafer W is then transferred to the periphery removing apparatus 70 by the wafer transfer device 40. In the periphery removing device 70, removal of the peripheral portion We of the first wafer W, that is, edge trimming is performed as illustrated in FIG. 15C (process St6 in FIG. 8).

The removal of the peripheral portion We may be performed by inserting the blade B into the interface between the first wafer W and the second wafer S, and the insertion position of the blade B may be decided based on the measurement result in the process St1.

The combined wafer T from which the peripheral portion We of the first wafer W has been removed is then transferred to the cleaning apparatus 80 by the wafer transfer device 40. In the cleaning apparatus 80, the first wafer W from which the peripheral portion We has been removed, and/or the second wafer S are cleaned (process St7 in FIG. 8).

Further, when a surface film remains on the front surface Sa of the second wafer S after the removal of the peripheral portion We, the surface film may also be removed, as shown in FIG. 15D.

Afterwards, the combined wafer T after being subjected to all the required processes is transferred to the transition device 30 by the wafer transfer device 40, and is then transferred to the cassette C on the cassette placement table 10 by the wafer transfer device 20. In this way, the series of processes of the wafer processing in the wafer processing system 1 are ended.

In addition, for the combined wafer T after being subjected to the edge trimming of the first wafer W, it may be inspected whether the edge trimming has been appropriately performed, that is, whether the peripheral portion We has been removed from the first wafer W by a required trim width (inspection of completeness).

As described above, in the edge trimming process according to another exemplary embodiment, the width (trim width) of the peripheral portion We removed from the first wafer W can be controlled uniform along the entire circumference of the first wafer W, as shown in FIG. 15C.

In the wafer processing system 1 according to the technique of the present disclosure, since the outer ends of the first wafer W and the second wafer S are independently detected by using the length measurement sensor, the irradiation positions of the interface laser light L1 and the internal laser light L2 can be decided by selecting either the outer end of the first wafer W or the outer end of the second wafer S as a reference depending on the purpose of the wafer processing. This position as a reference for the irradiation position of the laser light can be changed, by the control device 90, for each lot accommodated in the cassette C, or for each wafer processed in the wafer processing system 1.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
60: Internal modifying apparatus
70: Periphery modifying apparatus
90: Control device
220: Deviation amount detector
M1: Peripheral modification layer
S: Second wafer
T: Combined wafer
W: First wafer
Wc: Central portion
We: Peripheral portion

1. A processing method, comprising:
acquiring an eccentric amount between a first substrate and a second substrate, the first substrate and the second substrate being bonded to each other;
forming, by radiating laser light along a boundary between a peripheral portion of the first substrate and a central portion of the first substrate, a peripheral modification layer serving as a starting point of separation of the peripheral portion; and
removing the peripheral portion starting from the peripheral modification layer,
wherein in the forming of the peripheral modification layer, an irradiation position of the laser light is determined based on the eccentric amount.

2. The processing method of claim 1, further comprising:
measuring, by a length measurement sensor, a first horizontal distance between the length measurement sensor and an outer end of the first substrate; and
measuring, by the length measurement sensor, a second horizontal distance between the length measurement sensor and an outer end of the second substrate,
wherein the eccentric amount is calculated based on a deviation amount between the first substrate and the second substrate calculated from a difference between the first horizontal distance and the second horizontal distance.

3. The processing method of claim 1, further comprising:
capturing an image of a position of an outer end of the first substrate from above; and
capturing an image of a position of an outer end of the second substrate from below,
wherein the eccentric amount is calculated based on a difference between the captured image of the position of the outer end of the first substrate and the captured image of the position of the outer end of the second substrate.

4. The processing method of claim 1,
wherein the irradiation position of the laser light is determined based on an outer end of the first substrate.

5. The processing method of claim 1,
wherein a bonding region in which the first substrate and the second substrate are bonded to each other and a non-bonding region corresponding to chamfered portions formed at outer ends of the first substrate and the second substrate are formed at an interface between
the first substrate and the second substrate, and the irradiation position of the laser light is determined based on an inner end of the non-bonding region in a diametrical direction.

6. The processing method of claim 1,
wherein the irradiation position of the internal laser light is determined based on an outer end of the second substrate.

7. A processing method, comprising:
acquiring an eccentric amount between a first substrate and a second substrate, the first substrate and the second substrate being bonded to each other; and
forming, by radiating laser light to an interface between the first substrate and the second substrate, a bonding strength reduction region with reduced bonding strength between the first substrate and the second substrate at the interface,
wherein in the forming of the bonding strength reduction region, an irradiation position of the laser light is determined based on the eccentric amount.

8. The processing method of claim 7, further comprising:
forming, by radiating laser light along a boundary between a peripheral portion of the first substrate and a central portion of the first substrate, a peripheral modification layer serving as a starting point of separation of the peripheral portion; and
removing the peripheral portion starting from the peripheral modification layer,
wherein in the forming of the peripheral modification layer, an irradiation position of the laser light is determined based on the eccentric amount.

9. The processing method of claim 8,
wherein the irradiation position of the laser light is determined based on an outer end of the second substrate.

10. The processing method of claim 7, further comprising:
measuring, by a length measurement sensor, a first horizontal distance between the length measurement sensor and an outer end of the first substrate; and
measuring, by the length measurement sensor, a second horizontal distance between the length measurement sensor and an outer end of the second substrate,
wherein the eccentric amount is calculated based on a deviation amount between the first substrate and the second substrate calculated from a difference between the first horizontal distance and the second horizontal distance.

11. The processing method of claim 7,
wherein the irradiation position of the laser light is determined based on an outer end of the first substrate, and
the laser light is radiated from the second substrate toward the combined substrate.

12. The processing method of claim 7,
wherein the irradiation position of the laser light is determined based on an outer end of the second substrate, and
the laser light is radiated from the first substrate toward the combined substrate.

13. A processing system, comprising:
a deviation amount detector to acquire an eccentric amount between a first substrate and a second substrate, the first substrate and the second substrate being bonded to each other;
an internal modifier to radiate laser light along a boundary between a peripheral portion of the first substrate and a central portion of the first substrate to form a peripheral modification layer serving as a starting point for separation of the peripheral portion;
a periphery remover configured to remove the peripheral portion starting from the peripheral modification layer; and
circuitry configured to control an irradiation position of the laser light based on the eccentric amount.

14. A processing system, comprising:
a deviation amount detector to acquire an eccentric amount between a first substrate and a second substrate, the first substrate and the second substrate being bonded to each other;
an interface modifier configured to radiate interface laser light to an interface between the first substrate and the second substrate to form a bonding strength reduction region with reduced bonding strength at the interface; and
circuitry configured to control an irradiation position of the laser light based on the eccentric amount.

15. The processing system of claim 14, further comprising:
an internal modifier to radiate laser light along a boundary between a peripheral portion of the first substrate and a central portion of the first substrate to form a peripheral modification layer serving as a starting point for separation of the peripheral portion;
a periphery remover to remove the peripheral portion starting from the peripheral modification layer; and
circuitry configured to control an irradiation position of the laser light, which is radiated from the internal modifier, based on the eccentric amount.

16. The processing system of claim 14, wherein the circuitry is configured to:
determine the irradiation position of laser light based on an outer end of the first substrate, and
control the interface modifier to radiate laser light from a second substrate toward the combined substrate.

17. The processing system of claim 14, wherein the circuitry is configured to:
determine the irradiation position of the laser light based on an outer end of the second substrate, and
control the interface modifier to radiate the laser light from a first substrate toward the combined substrate.

18. The processing system of claim 13, further comprising:
a substrate holder configured to hold the combined substrate on a top surface thereof; and
a mover to move the substrate holder in a horizontal direction,
wherein the deviation amount detector is disposed at a position facing the substrate holder in a direction perpendicular to a moving direction of the substrate holder, or at a position facing the substrate holder on a movement axis of the substrate holder.

19. The processing system of claim 13, further comprising a substrate holder to hold the combined substrate,
wherein the deviation amount detector comprises a length measurement sensor disposed beside the substrate holder, and
the circuitry is configured to:
control the length measurement sensor to measure a first horizontal distance between the length measurement sensor and an outer end of the first substrate;
control the length measurement sensor to measure a second horizontal distance between the length measurement sensor and an outer end of the second substrate; and
calculate the eccentric amount based on a deviation amount between the first substrate and the second substrate calculated from a difference between the first horizontal distance and the second horizontal distance.

20. The processing system of claim 13,
wherein the deviation amount detector comprises:
a first imager to capture an image of a position of an outer end of the first substrate from above; and
a second imager to capture an image of a position of an outer end of the second substrate from below,
the circuitry is configured to calculate the eccentric amount based on a difference between the captured image of the position of the outer end of the first substrate and the captured image of the position of the outer end of the second substrate.
